(19) United States
(12) Patent Application Publication
(10) Pub. No.: US 2008/0128673 A1
(43) Pub. Date: Jun. 5, 2008

(54) TRANSISTOR OF PHASE CHANGE MEMORY DEVICE AND METHOD FOR MANUFACTURING THE SAME

(76) Inventors: Heon Yong CHANG, Gyeonggi-do (KR); Suk Kyoung HONG, Gyeonggi-do (KR); Hae Chan PARK, Chungcheongbuk-do (KR); Nam Kyun PARK, Seoul (KR)

Correspondence Address: LADAS & PARRY LLP, 224 SOUTH MICHIGAN AVENUE, SUITE 1600, CHICAGO, IL, 60604, US

(21) Appl. No.: 11/855,284

(22) Filed: Sep. 14, 2007

(30) Foreign Application Priority Data
Dec. 1, 2006 (KR) 10-2006-0120918

(51) Int. Cl. H01L 29/80; H01L 21/337

(52) U.S. Cl. 257/2; 257/287; 438/196; 257/E29.31; 257/E21.445

(57) ABSTRACT

A transistor for a phase change memory device includes a semiconductor substrate in which active regions are delimited by an isolation structure. A groove is defined on a surface of a gate forming area of each active region. Portions of the isolation structure, which are adjacent to the gate forming area of the active region, are recessed to expose side faces of the gate forming area of the active region. A gate is formed on the gate forming area of the active region over the gate forming area grooves and exposed side faces thereof as well as the recessed portions of the isolation structure. Junction areas are then formed in the active region on both sides of the gate to complete the transistor of a phase change memory device.

### CROSS-REFERENCE TO RELATED APPLICATIONS

The present application claims priority to Korean patent application number 10-2006-0120918 filed on Dec. 1, 2006, which is incorporated herein by reference in its entirety.

### BACKGROUND OF THE INVENTION

The present invention relates to a transistor of a phase change memory device and a method for manufacturing the same, and more particularly, to a transistor of a phase change memory device that causes the stable phase change of a phase change layer and a method for manufacturing the same.

In general, memory devices are largely divided between volatile RAM (random access memory) that loses stored information when power is interrupted and non-volatile ROM (read-only memory) that can continuously maintain the stored state of information even when power is interrupted. Volatile RAM includes memory such as DRAM (dynamic RAM) and SRAM (static RAM), whereas non-volatile ROM includes memory such as an EEPROM (electrically erasable and programmable ROM) flash memory device.

As is well known in the art, although the DRAM is an excellent memory device, the DRAM must have a high charge storing capacity. To this end, since the surface area of an electrode must be increased, it is difficult to obtain a high integration level. Further, in a flash memory device, a high operation voltage is required as compared to a source voltage due to the fact that two gates are stacked on each other. Accordingly, since a separate booster circuit is needed to form the necessary voltage for write and delete operations, it is difficult to accomplish a high integration level.

Due to these limitations, research to develop a novel memory device having a simple configuration capable of accomplishing a high level of integration while retaining the characteristics of a non-volatile memory device have been pursued. For example, recently, a phase change memory device has been disclosed in the art.

The phase change memory device is based on the fact that a phase change occurs in a phase change layer interposed between a lower electrode and an upper electrode from a crystalline state to an amorphous state due to current flow between the lower electrode and the upper electrode. The information stored in a cell is recognized by the medium of a difference in resistance between the crystalline state and the amorphous state.

The phase change memory device includes a chalcogenide layer which is a compound layer made of germanium (Ge), stibium (Sb) and tellurium (Te) that is employed as a phase change layer. As a current is applied, the phase change layer undergoes a phase change between the amorphous state and the crystalline state due to heat, specifically Joule heat. Accordingly, in the phase change memory device, the specific resistance of the phase change layer in the amorphous state is higher than the specific resistance of the phase change layer in the crystalline state. Considering this fact, in a read mode, sensing the current flowing through the phase change layer determines whether the information stored in the phase change cell has a logic value of ‘1’ or ‘0’.

It is known that, since the phase change memory device has a simple structure and adjoining cells do not interfere with each other, a high level of integration is possible. Also, since the phase change memory device has a read speed of several tens of ns (nano second) and a relatively high write speed of several tens to several hundreds ns, high speed operation is made possible.

Because the phase change memory device has excellent applicability to the conventional CMOS logic processes resulting in lower manufacturing costs, the phase change memory device is regarded as a highly advantageous memory device for commercialization purposes.

In the phase change memory device, in order to increase the amount of current used for the phase change, the width of a transistor, i.e. a channel width, must be increased. However, currently, as the size of a semiconductor chip shrinks due to high integration, the width of a transistor has also been decreased.

If the width of a transistor decreases, the current amount flowing from a drain to a source is reduced resulting in an unstable phase change of the phase change layer.

### SUMMARY OF THE INVENTION

Embodiments of the present invention are directed to a transistor of a phase change memory device that causes a stable phase change of a phase change layer and a method for manufacturing the same.

In one embodiment, a transistor for a phase change memory device comprises a semiconductor substrate in which active regions are delimited by an isolation structure, a groove is defined on a surface of a gate forming area of each active region, portions of the isolation structure that are adjacent to the gate forming area of the active region are recessed to expose side faces of the gate forming area of the active region; a gate formed on the gate forming area of the active region that has the groove on the surface thereof and is exposed on the side faces thereof, and on the recessed portions of the isolation structure; and junction areas formed in the active region on both sides of the gate.

The groove has a depth of 500˜1500 Å.

The groove is defined in the shape of a rectangular hexahedron.

The side faces of the gate forming area of the active region are exposed by a depth of 500˜1500 Å.

In another embodiment, a method for manufacturing a transistor of a phase change memory device comprises the steps of forming an isolation structure for delimiting active regions in a semiconductor substrate; defining a groove on a surface of a gate forming area of each active region by etching the semiconductor substrate, and recessing portions of the isolation structure, which are adjacent to the gate forming area of the active region, to expose side faces of the gate forming area of the active region; forming a gate on the gate forming area of the active region, which has the groove on the surface thereof and is exposed on the side faces thereof, and on the portions of the isolation structure, which are adjacent to the gate forming area of the active region and are recessed; and forming junction areas in the active region on both sides of the gate.

The step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of etching the semiconductor substrate and thereby defining a groove on a surface of a gate forming area of each active region; and recessing portions of the isolation structure, which are adjacent to the gate forming area of the active region defined with the groove, and thereby exposing side faces of the gate forming area of the active region.

The step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of recessing portions of the isolation structure, which are adjacent to a gate forming area of each active region, and thereby exposing side faces of the gate forming area of the active region; and etching the semiconductor substrate and thereby defining a groove on a surface of the gate forming area of the active region.

The step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of etching the semiconductor substrate and at the same time recessing portions of the isolation structure, which are adjacent to a gate forming area of each active region, and thereby defining a groove on a surface of the gate forming area of the active region and at the same time exposing side faces of the gate forming area of the active region.

The groove has a depth of 500˜1500 Å.

The groove is defined in the shape of a rectangular hexahedron.

The side faces of the gate forming area of the active region are exposed by a depth of 500˜1500 Å.

### BRIEF DESCRIPTION OF THE DRAWINGS

FIG. 1 is a perspective view illustrating a transistor of a phase change memory device in accordance with an embodiment of the present invention.

FIGS. 2A through 2D are perspective views illustrating the steps of a method for manufacturing a transistor of a phase change memory device in accordance with another embodiment of the present invention.

### DESCRIPTION OF SPECIFIC EMBODIMENTS

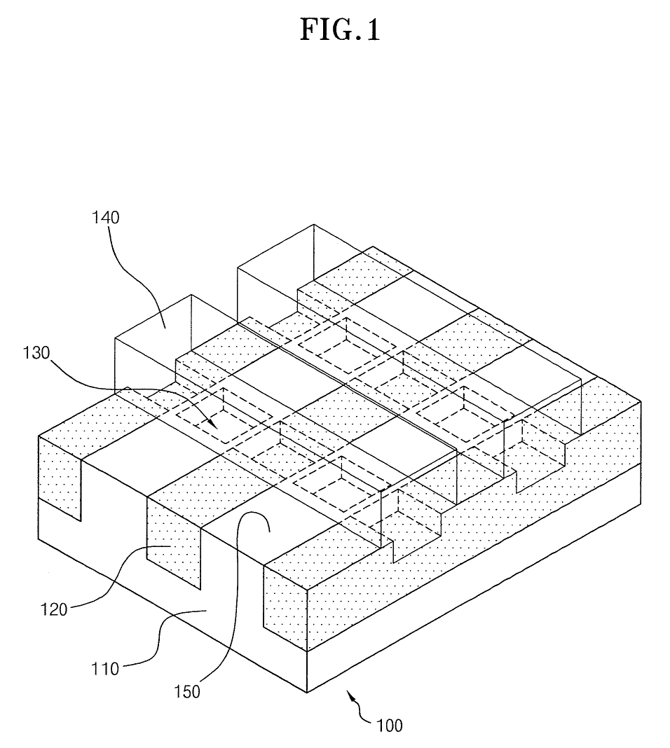

FIG. 1 is a perspective view illustrating a transistor of a phase change memory device in accordance with an embodiment of the present invention.

Referring to FIG. 1, active regions 110 are delimited by an isolation structure 120 that is formed in a semiconductor substrate 100. In each active region 110, a groove 130 is defined on the surface of a gate forming area. Portions of the isolation structure 120, which are adjacent to the gate forming area of the active region 110, are recessed such that the side faces of the gate forming area of the active region 110 are exposed. The groove 130 is defined to have a depth of 500˜1,500 Å and the side faces of the gate forming area of the active region 110 are exposed by a depth of 500˜500 Å by the recesses of the isolation structure 120.

A bar type gate 140 is formed on the gate forming area of the active region 110, which has the groove 130 defined on the surface thereof and is exposed on the side faces thereof, and on the portions of the isolation structure 120, which are adjacent to the gate forming area of the active region 110. Junction areas 150 are formed in the active region 110 on both sides of the gate 140.

Therefore, in the transistor of a phase change memory device according to an embodiment of the present invention, portions of the isolation structure on which the gate is located are recessed and the groove is defined in the portion of the active region on which the gate is located, the channel width of the transistor can be increased. Accordingly, since a current amount flowing from a drain to a source is increased, despite where the size of a cell is decreased, it is possible to secure a current amount required for the phase change of a phase changer layer. As a result, a stable phase change of the phase change layer can occur.

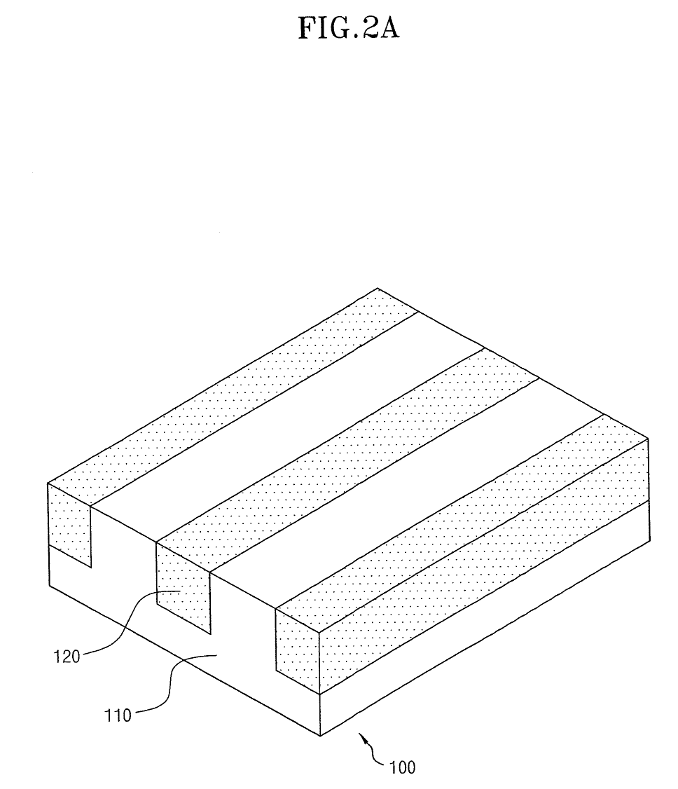

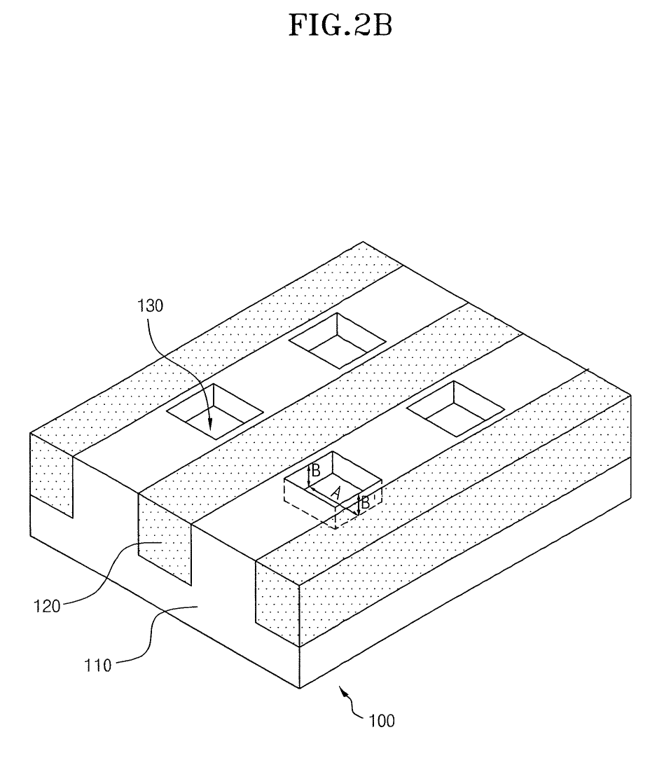

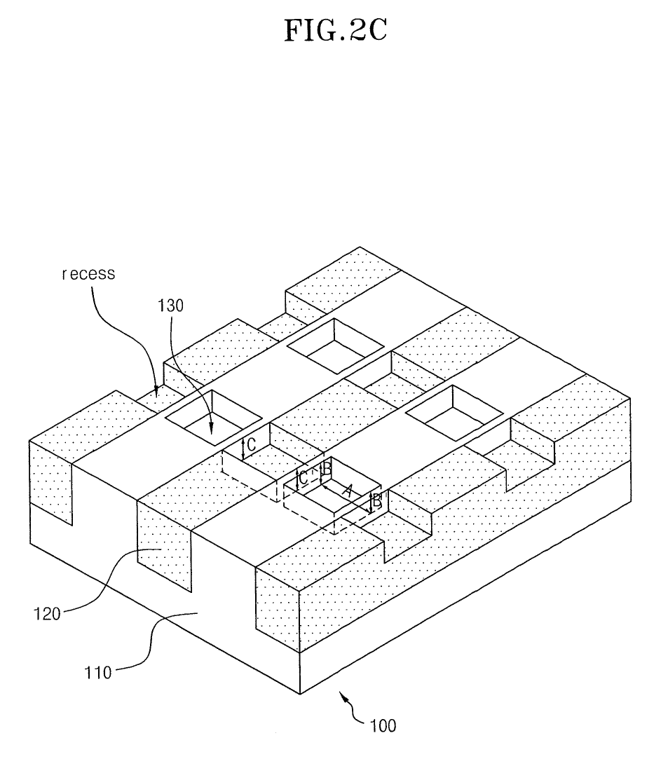

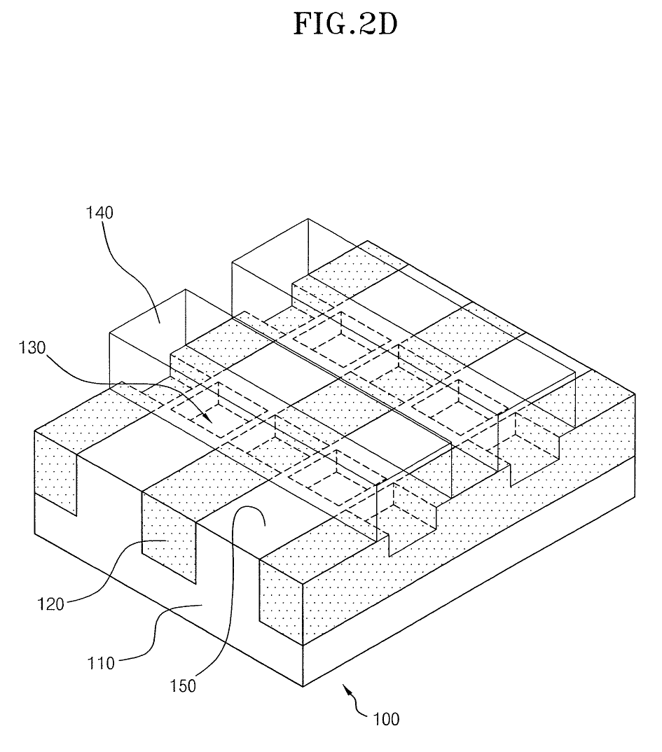

FIGS. 2A through 2D are perspective views illustrating the steps of a method for manufacturing a transistor of a phase change memory device in accordance with another embodiment of the present invention.

Referring to FIG. 2A, after preparing a semiconductor substrate 100 by dividing the semiconductor substrate into active regions 110 and isolation regions, an isolation structure 120 for delimiting the active regions 110 is formed in the isolation regions according to a well-known process.

Referring to FIG. 2B, by etching the semiconductor substrate 100, a groove 130 having a depth of 500˜1,500 Å is defined on the surface of a gate forming area of each active region 110. Preferably, the groove 130 is defined in the shape of a rectangular hexahedron that has a base A and a height B or B′.

Referring to FIG. 2C, portions of the isolation structure 120, which are adjacent to the gate forming area of the active region 110, i.e. on which a gate is subsequently located, are recessed such that the side faces C and C′ of the gate forming area of the active region 110 are exposed by a depth of 500˜1,500 Å.

Here, in an embodiment of the present invention, the groove 130 is defined by etching the gate forming area of the active region 110 of the semiconductor substrate 100. The portions of the isolation structure 120, which are adjacent to the gate forming area of the active region 110, are also recessed resulting in an increased channel width of the transistor over the same area when compared to the conventional art.

In detail, in an embodiment of the present invention, by forming the groove 130 on the surface of the gate forming area of the active region 110 to have a base A and a height B or B′, the channel width of the transistor can be increased by the height of the groove 130. Also, by recessing the portions of the isolation structure 120 which are adjacent to the gate forming area of the active region 110 thus exposing side faces C and C′ of the gate forming area of the active region 110, the channel width of the transistor can be further increased by a height of the side faces C and C′ of the exposed gate forming area.

As a result, in an embodiment of the present invention, the channel width can be increased by B or B′ and C or C′ as shown in FIG. 2C by etching the active region 110 and recessing the isolation structure 120 allowing a stable and increased current amount to be used for the phase change of a phase change layer.

Referring to FIG. 2D, after sequentially depositing gate materials on the active region 110 of the semiconductor substrate 100 which includes the partially recessed isolation structure 120, a bar type gate 140 is formed by etching the gate materials on the gate forming area of the active region 110.

Thereafter, junction areas 150 are formed by implanting impurity ions in the active region 110 on both sides of the gate 140. The formation of junction areas 150 completes the manufacture of the transistor for a phase change memory device according to an embodiment of the present invention is completed.

In the above-described embodiment of the present invention, after defining the groove on the surface of the gate forming area of the active region by etching the semiconductor substrate, the portions of the isolation structure, which are adjacent to the gate forming area of the active region, are recessed to expose the side faces of the gate forming area. However, in still another embodiment of the present invention, it can be envisaged that the portions of the isolation structure, which are adjacent to the gate forming area of the active region, are first recessed to expose the side faces of the gate forming area of the active region, and subsequently the groove is defined on the surface of the gate forming area of the active region by etching the semiconductor substrate.

Also, in a still further embodiment of the present invention, it can be contemplated that the portions of the isolation structure, which are adjacent to the gate forming area of the active region, are recessed at the same time when the semiconductor substrate is etched so that the side faces of the gate forming area of the active region are exposed at the same time as the groove is defined on the surface of the gate forming area of the active region.

As is apparent from the above description, in the present invention, the channel width of a transistor can be increased by defining a groove in the gate forming area of an active region of a semiconductor substrate and recessing portions of an isolation structure which are adjacent to the gate forming area of the active region. Therefore, in the present invention, by increasing the channel width of the transistor, a current amount flowing from a drain to a source can be increased. Accordingly, a stable phase change of a phase change layer can occur and it is possible to secure a stable current amount required for the phase change even when the size of a cell is decreased.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A transistor for a phase change memory device, comprising:
a semiconductor substrate wherein active regions are delimited by an isolation structure;
a groove is defined on a surface of a gate forming area of each active region;
recessed portions of the isolation structure adjacent to the gate forming area of the active region to expose side faces of the gate forming area of the active region;
a gate formed on the gate forming area of the active region, which has the groove on the surface thereof and is exposed on the side faces thereof, and on the recessed portions of the isolation structure; and
junction areas formed in the active region on both sides of the gate.

2. The transistor according to claim 1, wherein the groove has a depth of 500˜1500 Å.

3. The transistor according to claim 1, wherein the groove is defined in the shape of a rectangular hexahedron.

4. The transistor according to claim 1, wherein the side faces of the gate forming area of the active region are exposed by a depth of 500˜1500 Å.

5. A method for manufacturing a transistor of a phase change memory device, comprising the steps of:
forming an isolation structure for delimiting active regions in a semiconductor substrate;
defining a groove on a surface of a gate forming area of each active region by etching the semiconductor substrate, and recessing portions of the isolation structure, which are adjacent to the gate forming area of the active region, to expose side faces of the gate forming area of the active region;
forming a gate on the gate forming area of the active region, which has the groove on the surface thereof and is exposed on the side faces thereof, and on the portions of the isolation structure, which are adjacent to the gate forming area of the active region and are recessed; and
forming junction areas in the active region on both sides of the gate.

6. The method according to claim 5, wherein the step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of:
etching the semiconductor substrate and thereby defining a groove on a surface of a gate forming area of each active region; and
recessing portions of the isolation structure, which are adjacent to the gate forming area of the active region defined with the groove, and thereby exposing side faces of the gate forming area of the active region.

7. The method according to claim 5, wherein the step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of:
recessing portions of the isolation structure, which are adjacent to a gate forming area of each active region, and thereby exposing side faces of the gate forming area of the active region; and
etching the semiconductor substrate and thereby defining a groove on a surface of the gate forming area of the active region.

8. The method according to claim 5, wherein the step of defining a groove on a surface of a gate forming area of each active region by etching the semiconductor substrate, and recessing portions of the isolation structure, which are adjacent to the gate forming area of the active region, to expose side faces of the gate forming area of the active region, comprises the steps of:
etching the semiconductor substrate, and at the same time, recessing portions of the isolation structure, which are adjacent to a gate forming area of each active region, and thereby defining a groove on a surface of the gate forming area of the active region and at the same time exposing side faces of the gate forming area of the active region.

9. The method according to claim 5, wherein the groove has a depth of 500˜1500 Å.

10. The method according to claim 5, wherein the groove is defined in the shape of a rectangular hexahedron.

11. The method according to claim 5, wherein the side faces of the gate forming area of the active region are exposed by a depth of 500˜1500 Å.
